(19) United States
(12) Patent Application Publication
(10) Pub. No.: US 2009/0032870 A1
(43) Pub. Date: Feb. 5, 2009

(54) Semiconductor device and method for manufacturing same

(75) Inventor: Takeshi Iida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/216,665

(22) Filed: Jul. 9, 2008

(30) Foreign Application Priority Data
Jul. 31, 2007 (JP) 2007-198536

(51) Int. Cl. H01L 29/78; H01L 21/336

(52) U.S. Cl. 257/339; 438/297; 257/E29.261; 257/E21.417

(57) ABSTRACT

A semiconductor device comprising a field effect transistor having higher breakdown voltage by reducing electric field concentration between the drain region and a gate electrode is provided. A semiconductor device includes, on a silicon substrate, an n-well source region and an n-well drain region, which are formed over a surface layer thereof to be spaced apart from each other; and a gate electrode provided via a gate insulating film, said gate insulating film being formed to extend over said source region and said drain region. Further, LOCOS oxide film 180a is formed in the surface of the silicon substrate in the n-well drain region, and thus the LOCOS oxide film has a constricted portion in the cross sectional view, and the gate electrode is formed to extend across a constricted portion.

This application is based on Japanese patent application No 2007-198,536, the content of which is incorporated hereinto by reference.

### BACKGROUND

1. Technical Field

The present invention relates to a semiconductor device and a method for manufacturing thereof.

2. Related Art

A laterally diffused metal oxide semiconductor (LDMOS) field effect transistor has a structure that is capable of diffusing an impurity in vicinity of a drain region in transverse direction, which leads to a reduction in electric field concentration between the drain region and a gate electrode, achieving higher breakdown voltage. Typical example of the conventional LDMOS is described in Japanese Patent Laid-Open No. 2005-183,633. In LDMOS described in Japanese Patent Laid-Open No. 2005-183,633, an upper surface of a local oxidation of silicon (LOCOS) oxide film is etched to form concave portions, and the presence of the concave portion provides a reduction in electric field concentration around a region under the end section of the gate electrode of the LOCOS oxide film. Here, the LOCOS is a technology, which is useful in electrically isolating individual elements formed on a semiconductor substrate.

Nevertheless, there is still a need for providing an improved breakdown voltage characteristics in the conventional technology described in Japanese Patent Laid-Open No. 2005-183,633, since a concave portion is provided in the upper surface of the LOCOS oxide film. In addition, the conventional technology further requires an additional process for further etching the upper surface of the LOCOS oxide film to form the concave portion after forming the LOCOS oxide film.

The present invention is directed to providing a semiconductor device having a field effect transistor with higher breakdown voltage, which is achieved by providing a configuration of reducing electric field concentration between a drain region and a gate electrode. In addition, the present invention is also directed to providing a process for manufacturing such semiconductor device through simple operations.

### SUMMARY

According to one aspect of the present invention, there is provided a semiconductor device, comprising: a source region and a drain region, formed over a semiconductor substrate to be spaced apart from each other; a gate electrode provided via a gate insulating film, the gate insulating film being formed to extend over the source region and the drain region; and a local oxidation of silicon (LOCOS) oxide film formed in a surface of the semiconductor substrate in the drain region, wherein a constricted portion is provided in a cross section of the LOCOS oxide film, and the gate electrode is formed to extend across the constricted portion.

Since the constricted portion is provided in the cross section of the LOCOS oxide film formed in the surface of the semiconductor substrate in the drain region in the above-described configuration of the semiconductor device according to the present invention, an electric field concentration can be reduced around a region under the end section of the gate electrode of such LOCOS oxide film.

According to another aspect of the present invention, there is provided a method for manufacturing a semiconductor device, including: preparing a semiconductor substrate having a source region and a drain region, formed over a surface layer thereof to be spaced-apart from each other; sequentially forming a sacrificial oxide film and a silicon nitride film over said semiconductor substrate; patterning said silicon nitride film to form first and second openings for forming LOCOS oxide film over said sacrificial oxide film, said first and said second openings for forming LOCOS oxide film being two-dimensionally adjacent to each other; thermally oxidizing said semiconductor substrate to grow said sacrificial oxide film in said opening, thereby forming said LOCOS oxide film; removing said silicon nitride film; forming a gate insulating film over said semiconductor substrate so that said gate insulating film extend over said source region and said drain region; and forming a gate electrode over said gate insulating film.

Since said first and second openings for forming LOCOS oxide film are formed to be two-dimensionally adjacent to each other in the above-described configuration of the method for manufacturing the semiconductor device according to the present invention, both of the apexes of the LOCOS oxide film are unified. This unified structure provides forming a LOCOS oxide film having a constricted portion, allowing the manufacture of the semiconductor device with a simple manufacturing process, without a need for having an additional operation for forming a constricted portion after forming the LOCOS oxide film.

Thus, according to the present invention, a semiconductor device having a field effect transistor with higher breakdown voltage and a process for manufacturing such semiconductor device through simple operations is provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating a semiconductor device in one embodiment according to the present invention;

FIGS. 2A to 2C are cross-sectional views, illustrating a process for manufacturing a semiconductor device in the embodiment according to the present invention;

FIGS. 3A and 3B are cross-sectional views, illustrating a process for manufacturing a semiconductor device in the embodiment according to the present invention;

FIG. 4 is a diagram, showing a condition of impact ion created in vicinity of the drain region of the semiconductor device 100 in the embodiment according to the present invention;

FIG. 5 is a diagram, showing a condition of generation of impact ion in vicinity of the drain region in the conventional semiconductor device;

FIG. 6A is a diagram, showing distribution of electric field in vicinity of the drain region of the semiconductor device in the embodiment according to the present invention; and FIG. 6B is a diagram, showing distribution of electric field in vicinity of the drain region of the conventional semiconductor device;

FIG. 7A is a diagram, showing distribution of recombination in vicinity of the drain region of the semiconductor device in the embodiment according to the present invention;

FIG. 7B is a diagram, showing distribution of recombination in vicinity of the drain region of the conventional semiconductor device; and

FIG. 8 is a schematic plan view, shows a mask employed in the manufacture of a semiconductor device in the present embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

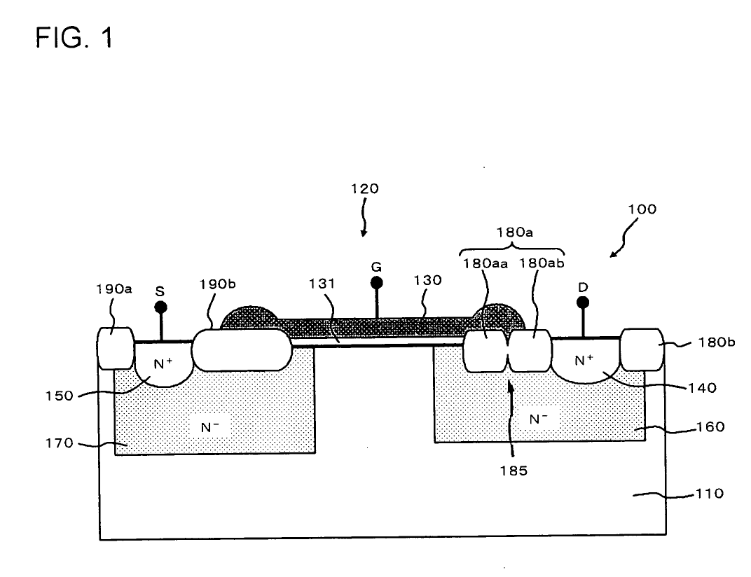

FIG. 1 shows a cross sectional structure of a semiconductor device 100 according to an embodiment of the present invention.

In the semiconductor device 100, a transistor 120 is formed in a silicon substrate 110.

In the diagram, “G” represents a gate, “S” represents a source, and “D” represents a drain.

An n-well drain region 160 and an n-well source region 170 are formed in a surface layer of the silicon substrate 110 so that these regions are disposed to be spaced apart from each other, serving as a pair of n type impurity-diffused regions, between which a channel region (not shown) is formed.

A gate electrode 130 is formed on a channel region disposed between the n-well drain region 160 and the n-well source region 170 via a gate insulating film 131, which is formed to extend over the n-well source region 170 and the n-well drain region 160. An end section of the n-well drain region 160 in the side of the gate electrode 130 extends across a constricted portion 185 in the side of the upper surface of the LOCOS oxide film 180a. Here, the term “to extend across a constricted portion 185” means to be formed so as to cover the constricted portion 185. The gate electrode 130 is doped with n-type impurity. Typical material for the gate insulating film 131 may include, for example, a silicon oxide film.

The n-well drain region 160 is provided with LOCOS oxide films 180a and 180b in the surface of the silicon substrate 110, and an n+ drain diffusion layer 140 doped with n-type impurity is provided between the LOCOS oxide films 180a and 180b. Besides, the n-well source region 170 is provided with LOCOS oxide films 190a and 190b in the surface of the silicon substrate 110, and an n+ source diffusion layer 150 doped with n-type impurity is provided between the LOCOS oxide films 190a and 190b.

The LOCOS oxide film 180a is formed in the surface of the silicon substrate 110 below the gate electrode 130 and above the n-well drain region 160 and in an end section of gate insulating film 131. A constricted portion 185 is provided in a cross section of the LOCOS oxide film 180a. The constricted portion 185 formed in the side of the upper surface of the LOCOS oxide film 180a is covered by gate electrode 130. The LOCOS oxide films 180 and 190 can be selectively formed, and serve as electrically isolating the individual elements. Typical material for the LOCOS oxide films 180 and 190 may include, for example, a silicon oxide film.

The constricted portion 185 is a concave portion formed in the top and the bottom of the oxide film 180a in the cross-sectional view. Another definition is that the constricted portion 185 is formed by unifying each one of two apexes formed in both ends of each of the LOCOS oxide film 180aa and the LOCOS oxide film 180ab. In addition, as will be described as follows, the thickness of the constricted portion 185 may be larger than the thickness of the sacrificial oxide film 201 before the silicon substrate 110 is thermally processed, and may be smaller than the thickness of the sacrificial oxide film 201 after the silicon substrate 110 is thermally processed. In addition, the side surface of the constricted portion 185 may be inclined. Preferable thickness of the constricted portion 185 is equal to or lowers than 500 nm. This allows obtaining the semiconductor device having a field effect transistor with higher breakdown voltage.

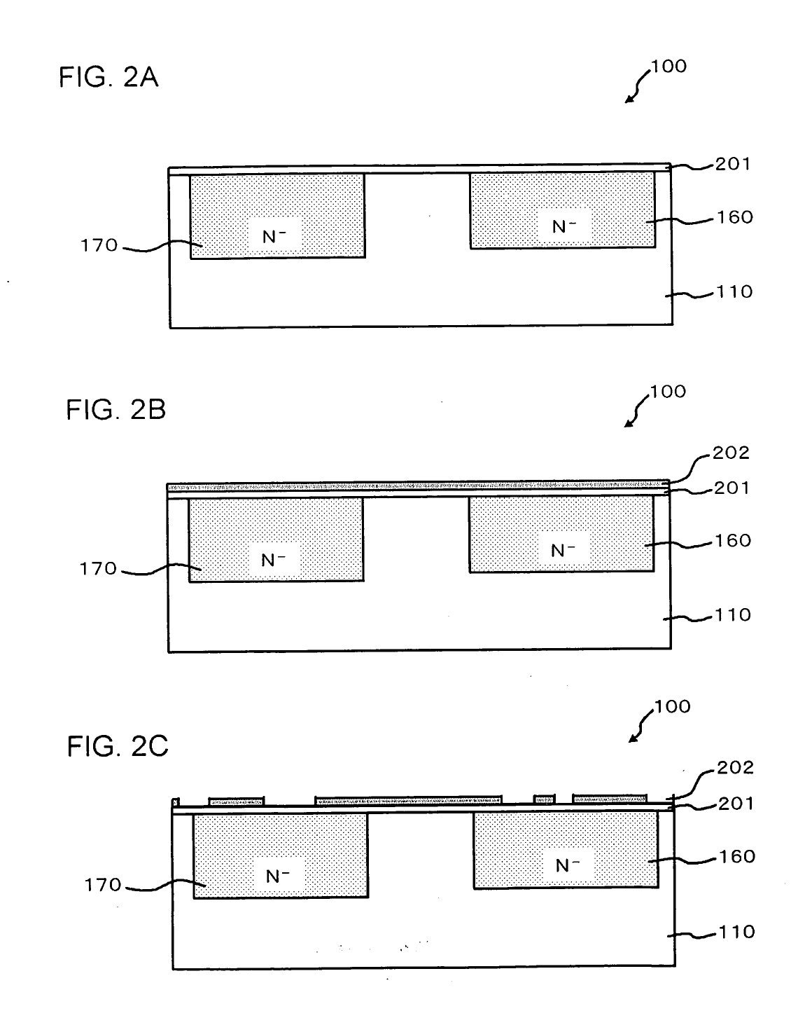

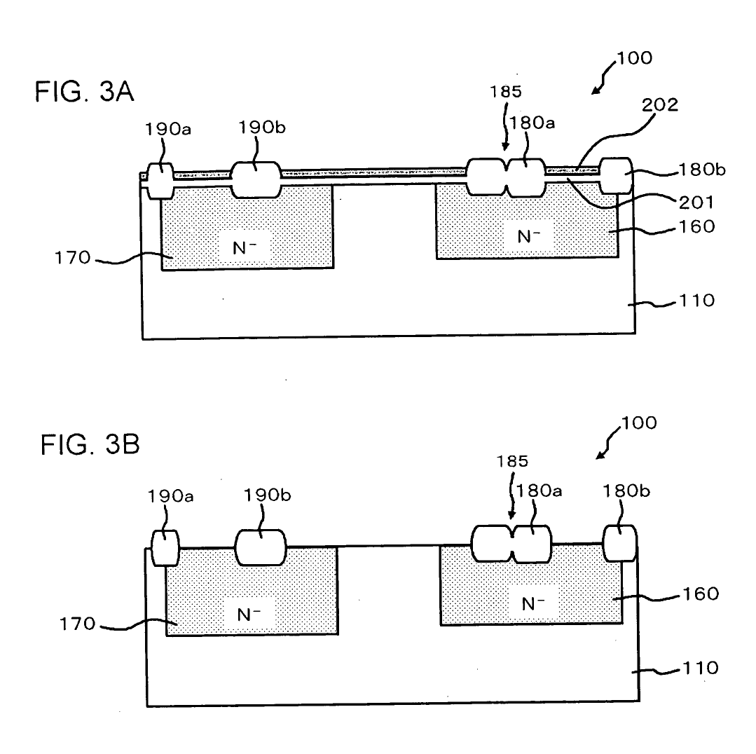

Next, a process for manufacturing the semiconductor device 100 shown in FIG. 1 will be described in reference to FIGS. 2A to 2C and FIGS. 3A and 3B.

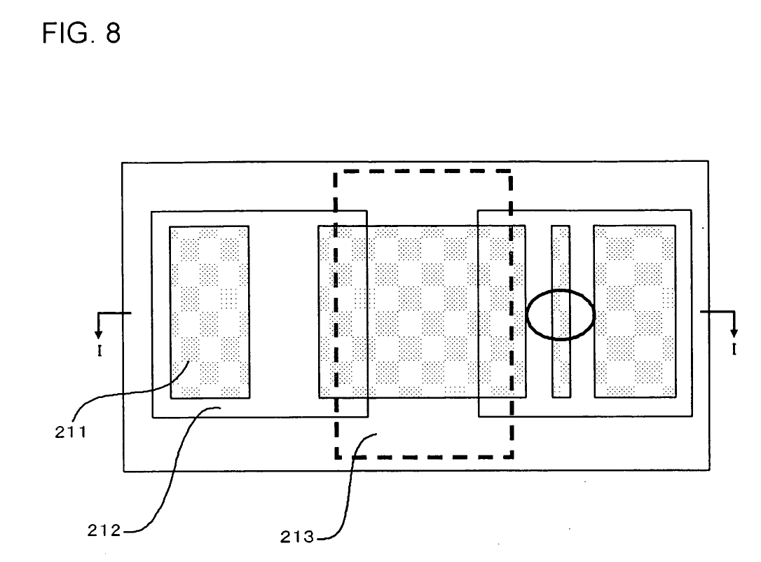

The n-well drain region 160 and the n-well source region 170 are formed in the surface layer of the silicon substrate 110 through a mask of an n-well mask 212 (see FIG. 8). First of all, the sacrificial oxide film 201 is formed on the silicon substrate 110 as shown in FIG. 2A, and then n type impurity is introduced in the silicon substrate 110 via a known technology to form the n-well drain region 160 and the n-well source region 170, which are spaced apart from each other.

Next, the LOCOS oxide films 180 and 190 are formed in the surface of the silicon substrate 110. As shown in FIG. 2B, the silicon nitride film 202 having higher oxidizing-resistance is formed on the sacrificial oxide film 201. Then, as shown in FIG. 2C, a patterning process is conducted through a mask of a field mask 211 (see FIG. 8) to partially remove the silicon nitride film 202, thereby forming respective openings in regions for forming the LOCOS oxide films. The first opening and the second opening, which are provided for forming the LOCOS oxide film 180aa and the LOCOS oxide film 180ab, respectively, are formed to be two-dimensionally adjacent to each other. The silicon nitride film 202 is formed between the first and the second openings. Then, the silicon substrate 110 is thermally oxidized to partially grow the sacrificial oxide film 201 within the openings to form the LOCOS oxide films 180 and 190, as shown in FIG. 3A. Thereafter, the residual portions of the silicon nitride film 202 are removed (FIG. 3B). The sacrificial oxide film 201 serves as a pad oxide film, and is typically composed of a silicon dioxide film, for example.

Since both ends of the LOCOS oxide films 180 and 190 covered with the silicon nitride film 202 also grow by the thermal oxidation as shown in FIG. 3A, apexes called “bird's beaks” are formed in both ends of the LOCOS oxide film 180 and 190, respectively. Since the portions of the sacrificial oxide film 201 grown within the first and the second openings create the first opening and the second opening for forming the LOCOS oxide films, which are two-dimensionally adjacent to each other, one of the bird's beaks formed in the ends of the LOCOS oxide film 180aa is unified to one of the bird's beaks formed in the ends of the LOCOS oxide film 180ab. This allows creating the LOCOS oxide film 180a having a constricted portion 185. Since the constricted portion 185 is formed at the same process operation as the LOCOS oxide film 180a is formed, no additional process operation for forming the constricted portion 185 is required after the LOCOS oxide film 180a is formed. Alternatively, a thermal oxidation may be conducted after the silicon nitride film 202 removed to unify the end of the LOCOS oxide film 180aa and the end of the LOCOS oxide film 180ab, as shown in FIG. 3B.

As shown in FIG. 8, the LOCOS oxide films 180aa and 180ab are formed to be parallelly arranged in the region surrounded by a circle in the top view of the field mask 211.

Subsequently, a channel region (not shown) is exposed over the surface of the silicon substrate 110, and then the gate insulating film 131 is formed on the silicon substrate 110 so as to extend over the n-well source region 170 and the n-well drain region 160, and the gate electrode 130 is formed thereon through a mask of a gate poly mask 213 (cf. FIG. 8). The gate electrode 130 is formed to extend over the LOCOS oxide film 180a and the LOCOS oxide film 190b, and is also formed to extend across the concave portion in the upper surface of the oxide film 180a.

Subsequently, n type impurity such as phosphorus (P), arsenic (As) and the like is injected into the n-well drain region 160 and the n-well source region 170 to form the n+ drain diffusion layer 140 and the n+ source diffusion layer 150, respectively. The semiconductor device 100 shown in FIG. 1 is manufactured in such procedure.

Next, advantageous effects obtainable by employing the configuration of the semiconductor device 100 shown in FIG. 1 will be described. In the semiconductor device 100 shown in FIG. 1, the LOCOS oxide film 180a of the transistor (FET) 120 has a cross section including a constricted portion 185. Thus, an electric field concentration is reduced around a region under the end section in the side of the gate electrode 130 of the LOCOS oxide film 108a. For the purpose of reducing such electric field concentration, typical conventional technology involves that only an upper surface of the LOCOS oxide film is etched to form a concave portion so that an electric field concentration is reduced around a region under the end section in the side of the gate electrode of the LOCOS oxide film. On the contrary, since the LOCOS oxide film 180a in the semiconductor device of the present embodiment has the concave portions in the upper side and the bottom side thereof, further relaxation of the electric field concentration can be achieved. Further, as described above, the constricted portion 185 of the LOCOS oxide film 180a is formed at the same process operation as the LOCOS oxide film 180a is formed. While the conventional technology requires an additional process operation for etching the upper surface of the LOCOS oxide film for forming a concave portion. On the contrary, the above-described configuration according to the present embodiment does not require such additional process operation, so that the semiconductor devices can be manufactured by the simple process.

Generation of impact ion, distribution of electric field and distribution of recombination are simulated for the semiconductor device 100 in the present embodiment, under the conditions that a voltage of 60 V is applied to the n+ drain diffusion layer 140, a voltage of 0 V is applied to the gate electrode 130 and a voltage of 0 V is applied to the n+ source diffusion layer 150.

Results of the simulation will be described as follows.

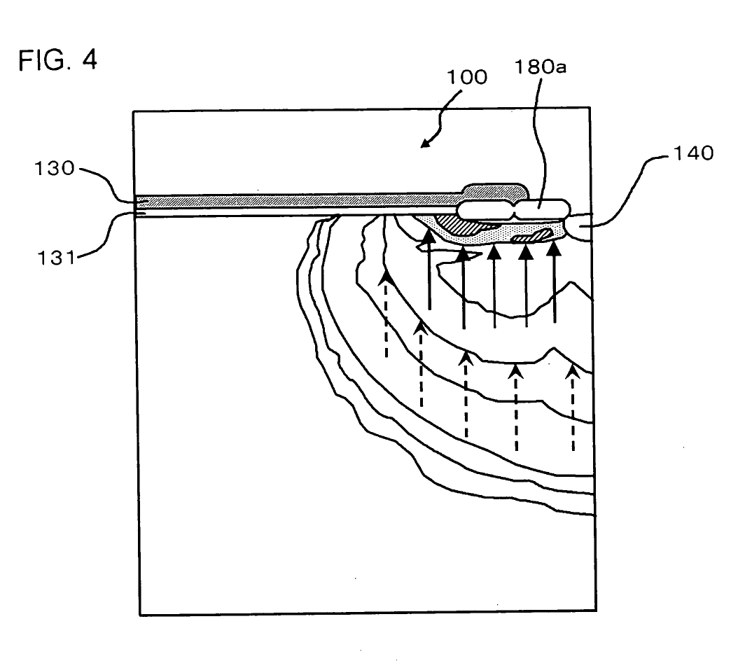

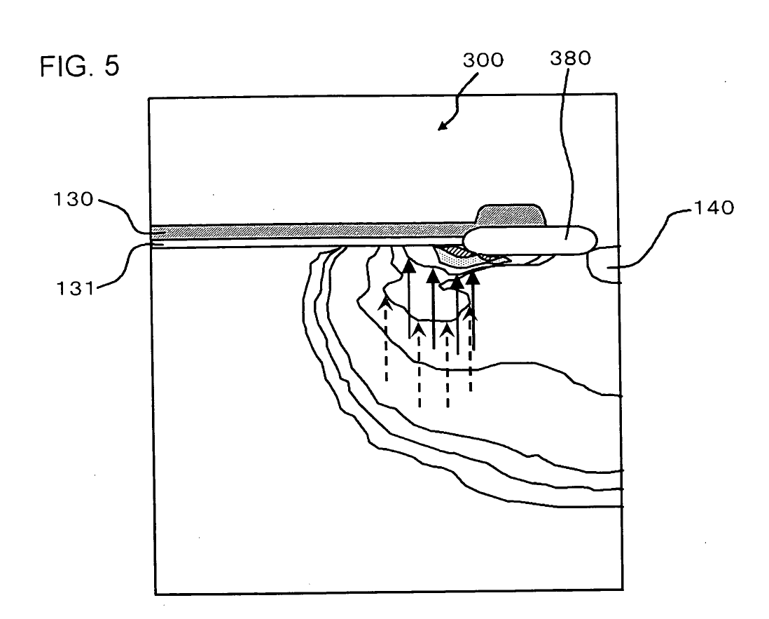

FIG. 4 is a diagram, showing conditions of generation of impact ion in vicinity of the drain region of the semiconductor device 100 in the present embodiment. FIG. 5 is a diagram, showing conditions of generation of impact ion in vicinity of the drain region of the conventional semiconductor device 300.

As shown by a hatched line section in FIG. 5, impact ion in vicinity of the drain region of the conventional semiconductor device 300 is concentrated around a region under the end section in the side of the gate electrode 130 of the LOCOS oxide film 380, leading to a disturbance for providing an improved breakdown voltage. On the contrary, as shown by a hatched line section in FIG. 4, impact ion in vicinity of the drain region of the semiconductor device 100 in the present embodiment extends over the entire lower section of the LOCOS oxide film 180a, thereby reducing concentration of impact ion. This allows providing an improved breakdown voltage characteristic of the semiconductor device 100.

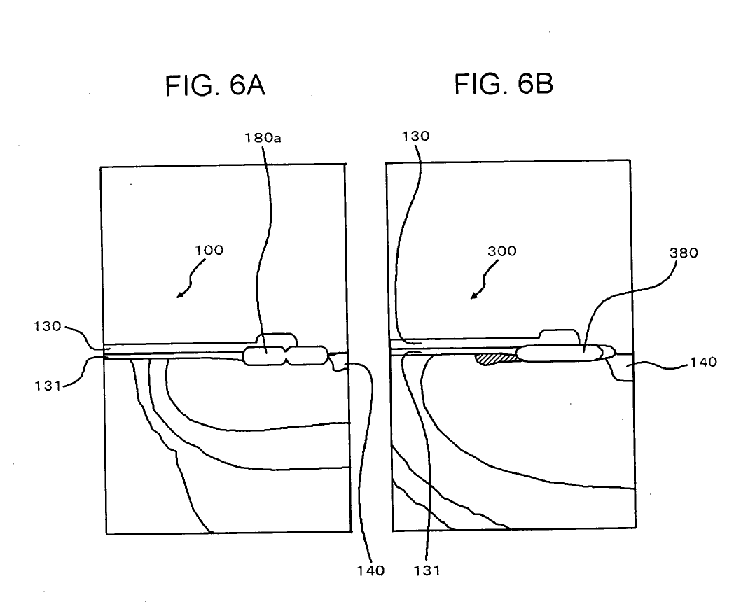

FIG. 6A is a diagram, showing distribution of electric field in vicinity of the drain region of the semiconductor device 100 in the present embodiment, and FIG. 6B is a diagram, showing distribution of electric field in vicinity of the drain region of the conventional semiconductor device 300. While electric field in vicinity of the drain region of the conventional semiconductor device 300 is concentrated around a region under the end section in the side of the gate electrode 130 of the LOCOS oxide film 380 as shown by a hatched line section of FIG. 6B, such electric field concentration is not observed in the electric field created in vicinity of the drain region of the semiconductor device 100 in the present embodiment, as shown in FIG. 6A. This allows providing an improved breakdown voltage characteristic of the semiconductor device 100.

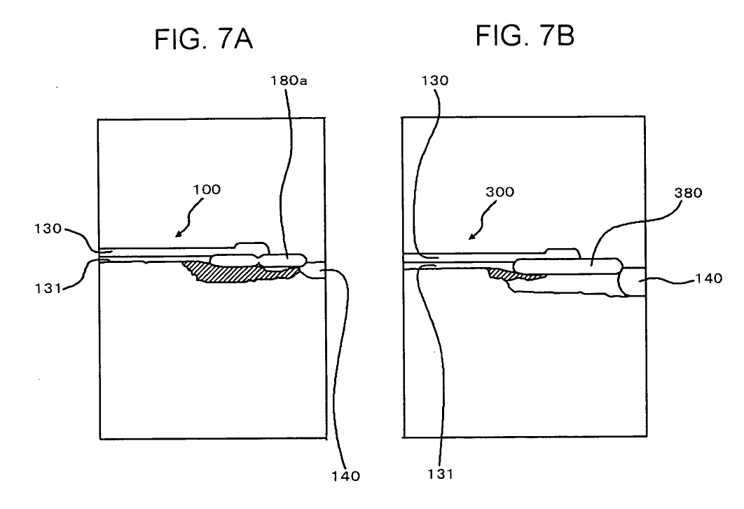

FIG. 7A is a diagram, showing distribution of recombination in vicinity of the drain region of the semiconductor device 100 in the present embodiment, and FIG. 7B is a diagram, showing distribution of recombination in vicinity of the drain region of the conventional semiconductor device 300. While recombination points in vicinity of the drain region of the conventional semiconductor device 300 is concentrated around a region under the end section in the side of the gate electrode 130 of the LOCOS oxide film 380 as shown by a hatched line section of FIG. 7B, recombination points created in vicinity of the drain region of the semiconductor device 100 extends over the entire lower section of the LOCOS oxide film 180a in the present embodiment, as shown in FIG. 7A. This allows providing an improved breakdown voltage characteristic of the semiconductor device 100.

While the embodiments of the present invention has been fully described above in reference to the annexed figures, it is intended to present these embodiments for the purpose of illustrations of the present invention only, and various modifications other than that described above are also available. For example, while the exemplary implementation provided with a single constricted portion in the cross section of the LOCOS oxide film has been described in the preferred embodiment of the present invention, a plurality of constricted portions may alternatively be provided. This allows providing further improved breakdown voltage characteristic of the device. Further, a position of the opening for forming the LOCOS oxide film may be adjusted by suitably selecting a mask. Further, openings for forming the LOCOS oxide film, which are two-dimensionally adjacent to each other, may be further provided. In this case, suitable design can be achieved by dividing a mask employed for forming the openings or the like. This allows achieving a manufacture of a semiconductor device having improved breakdown voltage characteristics in simple manufacturing process.

It is apparent that the present invention is not limited to the above embodiment, and may be modified and changed without departing from the scope and spirit of the invention.

What is claimed is:

1. A semiconductor device, comprising:
a source region and a drain region, formed over a semiconductor substrate to be spaced apart from each other;
a gate electrode provided via a gate insulating film, said gate insulating film being formed to extend over said source region and said drain region; and
a local oxidation of silicon (LOCOS) oxide film formed in a surface of said semiconductor substrate in said drain region,
wherein a constricted portion is provided in a cross section of said LOCOS oxide film, and said gate electrode is formed to extend across said constricted portion.

2. The semiconductor device as set forth in claim 1, wherein
said LOCOS oxide film has apexes in both ends thereof, and
said constricted portion is a section at the union of said apexes of said LOCOS oxide film.

3. A method for manufacturing a semiconductor device, including:
preparing a semiconductor substrate having a source region and a drain region, formed over a surface layer thereof to be spaced apart from each other;
sequentially forming a sacrificial oxide film and a silicon nitride film over said semiconductor substrate;
patterning said silicon nitride film to form first and second openings for forming LOCOS oxide film over said sacrificial oxide film, said first and second openings for forming LOCOS oxide film being two-dimensionally adjacent to each other;
thermally oxidizing said semiconductor substrate to grow said sacrificial oxide film in said opening, thereby forming said LOCOS oxide film;
removing said silicon nitride film;
forming a gate insulating film over said semiconductor substrate so that said gate insulating film extend over said source region and said drain region; and
forming a gate electrode over said gate insulating film.
